(19) United States
(12) Patent Application Publication
(10) Pub. No.: US 2010/0258902 A1
(43) Pub. Date: Oct. 14, 2010

(54) METHOD FOR FORMING FUSE IN SEMICONDUCTOR DEVICE

(75) Inventor: Mi Hyeon JO, Jeollanam-do (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/645,090

(22) Filed: Dec. 22, 2009

(30) Foreign Application Priority Data
Apr. 8, 2009 (KR) 10-2009-0030345

(51) Int. Cl. H01L 23/525; H01L 21/768

(52) U.S. Cl. 257/529; 438/601; 257/E21.592; 257/E23.149

(57) ABSTRACT

A method for forming a fuse in a semiconductor device is disclosed. The method for forming the fuse in the semiconductor device forms an interlayer insulating layer when forming a fuse, and forms neighboring metal lines having different thicknesses using a zigzag-opened mask, thus preventing a neighboring fuse of a fuse to be blown from being damaged. A method for manufacturing the semiconductor device deposits a first interlayer insulating layer on a semiconductor substrate, patterns the first interlayer insulating layer using a zigzag-opened pad type mask such that the first interlayer insulating layer has different step heights where the same step height is arranged at every second step height location, deposits a second interlayer insulating layer, patterns the second interlayer insulating layer, and buries a metal on an entire surface, and planarizes the metal until the second interlayer insulating layer is exposed, thus forming a metal pattern.

### CROSS-REFERENCE TO RELATED APPLICATION

The priority of Korean patent application No. 10-2009-0030345 filed on Apr. 8, 2009, the disclosure of which is hereby incorporated in its entirety by reference, is claimed.

### BACKGROUND OF THE INVENTION

The present invention relates to a method for forming a fuse in a semiconductor device, and more particularly to a method for forming an interlayer insulating layer when forming a fuse, and forming neighboring metal lines having different thicknesses using a zigzag-opened mask, so that it prevents a neighboring fuse of a fuse to be blown from being damaged.

A semiconductor device such as a memory includes a great number of fine cells. Although a defect occurs in any of the fine cells, it is impossible for the semiconductor device to be normally operated, so that the semiconductor device is determined to be a defective semiconductor device. With the increasing integration degree of the semiconductor device, the probability of generating a defective cell in the semiconductor device is gradually increased. Provided that the entirety of the semiconductor device is discarded due to a defect generated in only a few cells among all cells contained in the semiconductor device, the discarding of the entirety of the semiconductor device is cost ineffective and is far from efficient.

In order to solve the above-mentioned problems, a Dynamic Random Access Memory (DRAM) uses a redundant cell (also called a redundancy cell) which is capable of substituting for a defective cell using a redundant memory cell included in the memory cell, resulting in an increased production yield. The configuration principles and the operation method of the redundant cell will hereinafter be described in detail.

If a wafer process is completed, a test is carried out on the wafer so that a defective memory cell can be found. Subsequently, an address of the defective memory cell is replaced with an address of a redundant memory cell. In the case of actually using a corresponding memory, if an address of a defective memory cell is entered, the redundant memory cell replaced with the defective memory cell is selected.

A fuse is generally formed of polysilicon or tungsten silicide. However, the polysilicon or tungsten silicide has high resistivity so that it is inappropriate to form a high-speed and highly-integrated semiconductor device. As a result, a metal line formed of low resistance material has been widely used in the fuse.

A laser beam is generally used to blow (or cut) the fuse. In the case of blowing the fuse connected to a defective memory cell using the laser beam, the degree of dispersion of an insulating layer located at an upper part of the fuse is of importance. In more detail, if it is assumed that the degree of dispersion of the insulating layer located at the upper part of the fuse is non-uniform, the fuse is not normally blown due to irregular reflection of the laser beam, resulting in an erroneous or faulty operation in the redundant cell.

In recent times, as information media such as computers have rapidly come into wide use, it is necessary for a memory device or a semiconductor device including a memory to be operated at high speed and have high storage capacity. In order to satisfy the above requirements, a critical dimension is rapidly decreased, so that a highly integrated semiconductor device is formed and a multilayered wiring is applied to a metal wiring acting as an electrical transmission part.

Accordingly, as the integration degree of a semiconductor device is gradually increased, the size of a fuse contained in either a memory device or a semiconductor device including a memory is gradually reduced whereas the stress caused by a multilayered wiring is gradually increased. As a result, the fuse is damaged and a repairing function of the semiconductor device is not normally carried out.

FIGS. 1A to 1E are cross-sectional views illustrating a method for forming a fuse having a metal layer that has a thickness different from that of a general wiring contained in a semiconductor device so as to prevent a neighboring fuse instead of a desired line from being damaged in a conventional process for blowing the fuse.

Referring to FIG. 1A, a first interlayer insulating layer 13 is deposited on a semiconductor substrate 11. After a photoresist layer is deposited on the first interlayer insulating layer 13, a predetermined part corresponding to a difference ‘a’ in thickness (i.e., a step height ‘a’) between a wiring and a fuse is etched so that a step height occurs in the first interlayer insulating layer 13.

Referring to FIG. 1B, the photoresist layer 15 deposited on the first interlayer insulating layer 13 is removed, and an etching prevention layer 17 is deposited on the entire surface.

Referring to FIG. 1C, a second interlayer insulating layer 19 is deposited on the entire surface. Referring to FIG. 1D, the photoresist layer 21 is deposited on the second interlayer insulating layer 19, and an exposure and development process and an etching process are sequentially performed, so that a second interlayer insulating layer pattern 19a, where a desired wiring and a fuse will be formed, is formed.

Referring to FIG. 1E, metal material is buried in an etch trench of the second interlayer insulating layer pattern 19a to form a wiring 21a and a fuse 21b which have a step height ‘a’ therebetween. At this time, the metal material may be formed of copper (Cu).

The fuse and the wiring formed according to the above-mentioned processes shown in FIGS. 1A to 1E are shown in FIGS. 2A to 2C.

FIG. 2A is a top plan view illustrating a fuse pattern formed in FIGS. 1A to 1E. FIG. 2B is a cross-sectional view illustrating the fuse pattern taken along the line A-A′ of FIG. 2A. FIG. 2C is a cross-sectional view illustrating the fuse pattern taken along the line B-B′ of FIG. 2a. FIG. 2D is a cross-sectional view illustrating the fuse pattern taken along the line C-C′ of FIG. 2A.

In the above-mentioned fuse forming method according to the related art, as shown in FIGS. 2B to 2D, a metal layer forming the fuse is thinner than a metal layer forming a general wiring for providing the power, and has better uniformity than that of the metal layer forming the general wiring. When a thickness of the fuse is reduced, resistance of the fuse is increased, resulting in a reduction in speed of transmission of power and signals.

### BRIEF SUMMARY OF THE INVENTION

Various embodiments of the present invention are directed to providing a method for forming a fuse in a semiconductor device that substantially obviates one or more problems due to limitations and disadvantages of the related art.

An aspect of the present invention is to provide a method for forming a fuse in a semiconductor device, which firstly forms an interlayer insulating layer when forming a fuse, and forms neighboring metal parts having different thicknesses using a zigzag-opened mask, so that it prevents a neighboring fuse of a fuse to be blown from being damaged.

In accordance with an aspect of the present invention, A method for manufacturing a semiconductor device having a fuse, the method includes depositing a first interlayer insulating layer over a semiconductor substrate, patterning the first interlayer insulating layer to form a first trench in a fuse area so that the first trench is arranged in a zigzag manner in the fuse area, depositing a second interlayer insulating layer over the patterned first interlayer insulating layer and within the first trench, patterning the second interlayer insulating layer to form first and second holes, the second hole extending into the trench and having a greater depth than the first hole and filling conductive material in the first and the second holes to form a first metal pattern and a second metal pattern, respectively, wherein the first metal pattern defines a blowing region and the second metal pattern defines a fuse line.

Preferably, the method may further include, after patterning the first interlayer insulating layer, depositing an etch stop layer over the patterned first interlayer insulating layer.

Preferably, the patterning of the first interlayer insulating layer may include depositing a photoresist layer over the first interlayer insulating layer and performing an etching process using a mask,

Preferably, the patterning of the second interlayer insulating layer may include depositing a photoresist layer on the second interlayer insulating layer and performing an exposure and development process using a mask to form a second interlayer insulating layer pattern.

Preferably, the conductive material is formed of copper (Cu).

Preferably, the first and the second metal patterns are arranged alternatively either in horizontal or vertical direction.

In one embodiment, a semiconductor device has a first fuse that comprises: a first line pattern provided between first and second ends; a first metal pattern defining a first fuse line and having a first thickness, the first metal pattern being provided between the first end and the second end; and a second metal pattern defining a first blowing region and having a second thickness, the second metal pattern being provided between the first metal pattern and the second end, the second thickness being different than the first thickness, wherein the first line pattern comprises the first and second metal patterns.

In yet another embodiment, the semiconductor device includes a second fuse provided laterally adjacent to the first fuse. The second fuse comprises a second line pattern provided between the first and second ends, the second line pattern including third and fourth metal patterns. The third metal pattern defines a second fuse line and has the first thickness, the third metal pattern being provided between the first end and second end. The fourth metal pattern defines a second blowing region and has the second thickness, the fourth metal pattern being provided between the third metal pattern and the first end.

### BRIEF DESCRIPTION OF THE DRAWINGS

FIGS. 1A to 1E are cross-sectional views illustrating a method for forming a fuse area according to the related art.

FIG. 2A is a top plan view illustrating a fuse area formed by processes shown in FIGS. 1A to 1E, FIG. 2B is a cross-sectional view illustrating a fuse area taken along a line A-A′ of FIG. 2A, FIG. 2C is a cross-sectional view illustrating a fuse area taken along a line B-B′ of FIG. 2A, and FIG. 2D is a cross-sectional view illustrating a fuse area taken along a line C-C′ of FIG. 2A.

FIGS. 3A to 3F are cross-sectional views illustrating a method for forming a fuse area according to embodiments of the present invention.

FIG. 4A is a top plan view illustrating a fuse area formed by processes shown in FIGS. 3A to 3F, FIG. 4B is a cross-sectional view illustrating a fuse area taken along a line A-A′ of FIG. 4A, FIG. 4C is a cross-sectional view illustrating a fuse area taken along a line B-B′ of FIG. 4A, and FIG. 4D is a cross-sectional view illustrating a fuse area taken along a line C-C′ of FIG. 4A.

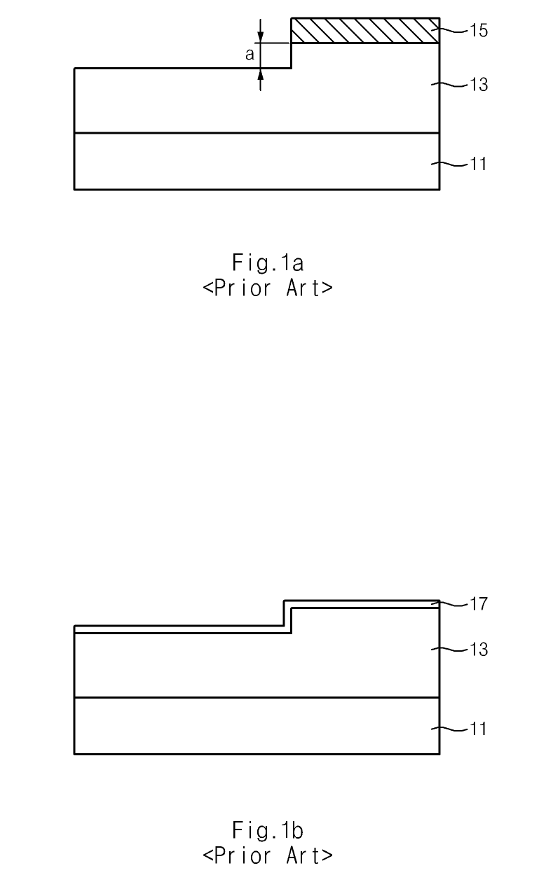

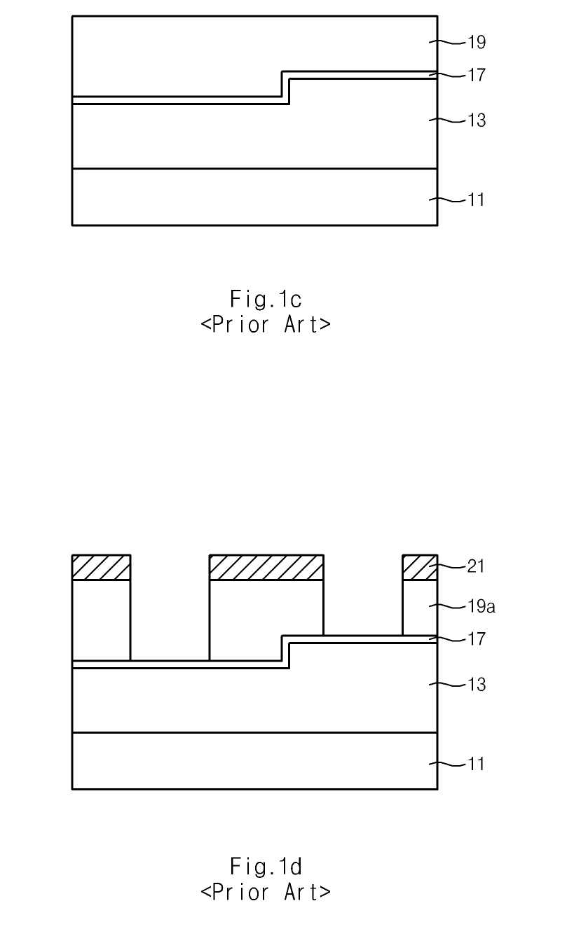

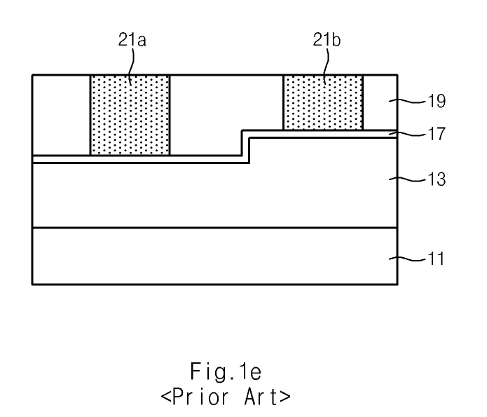

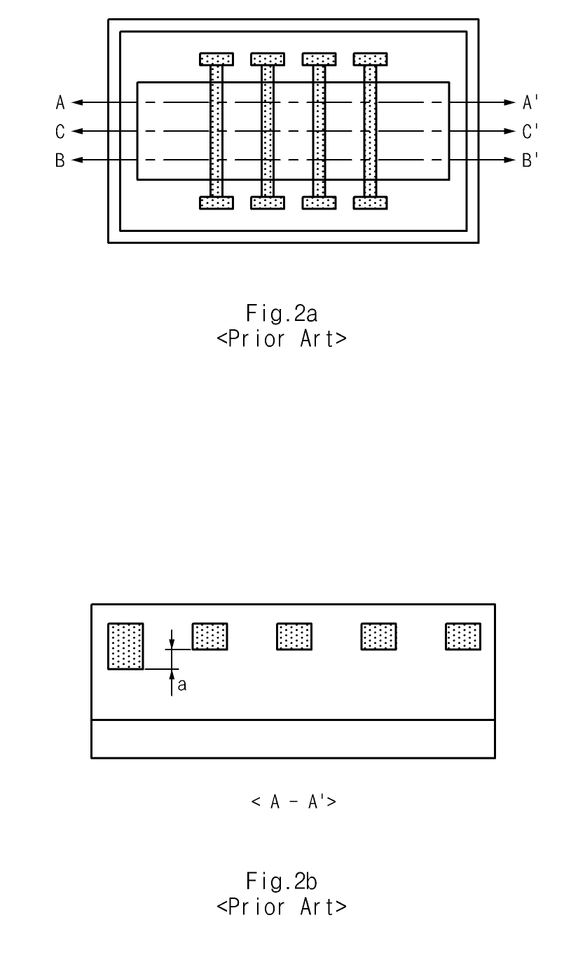

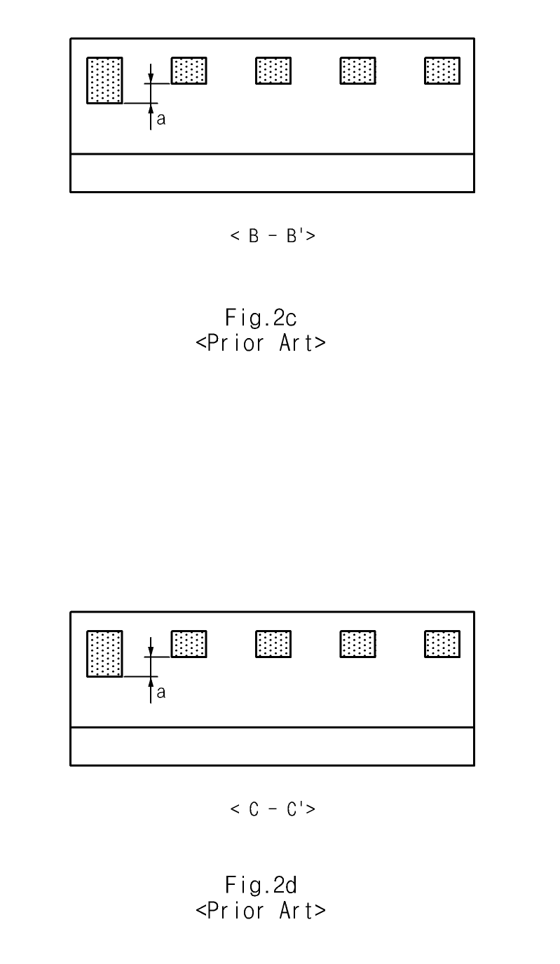

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

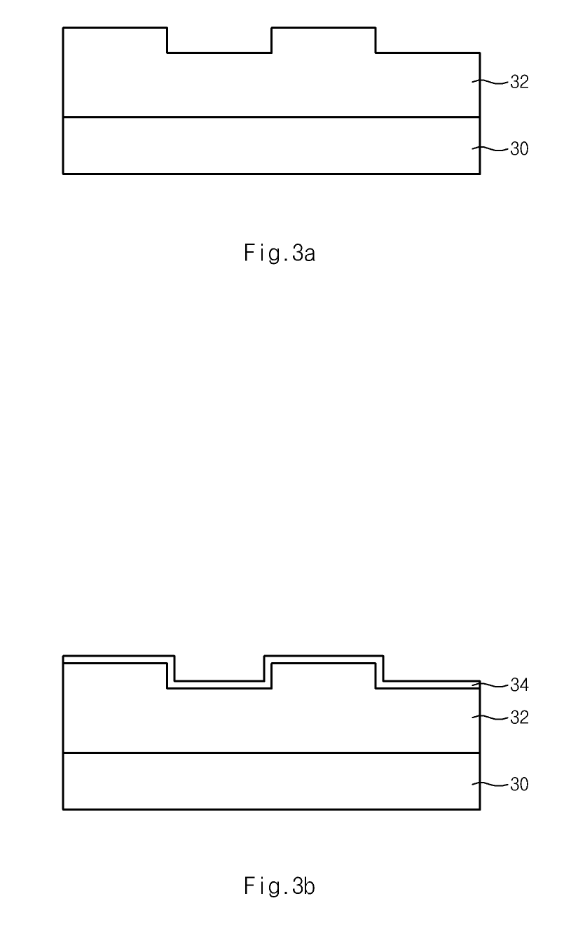

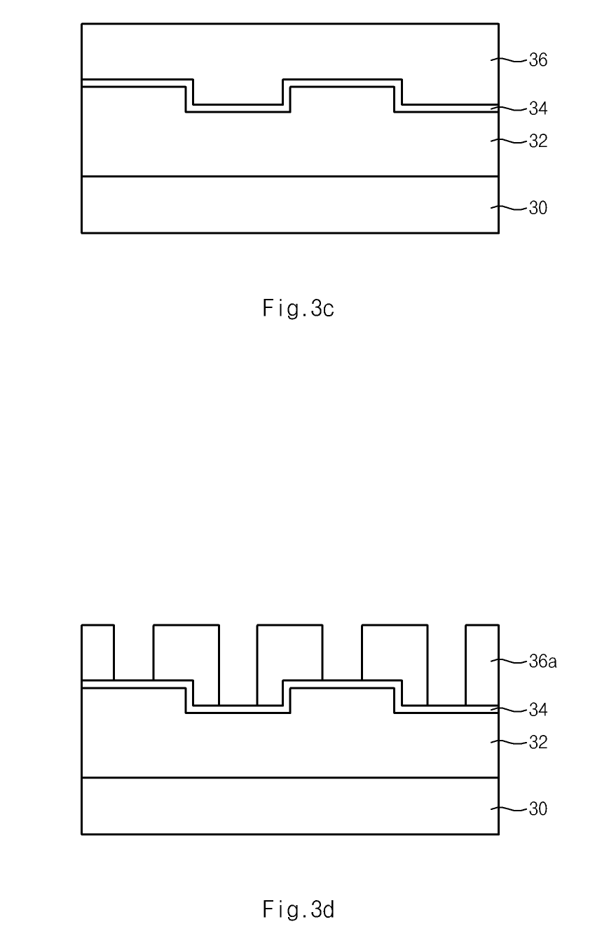

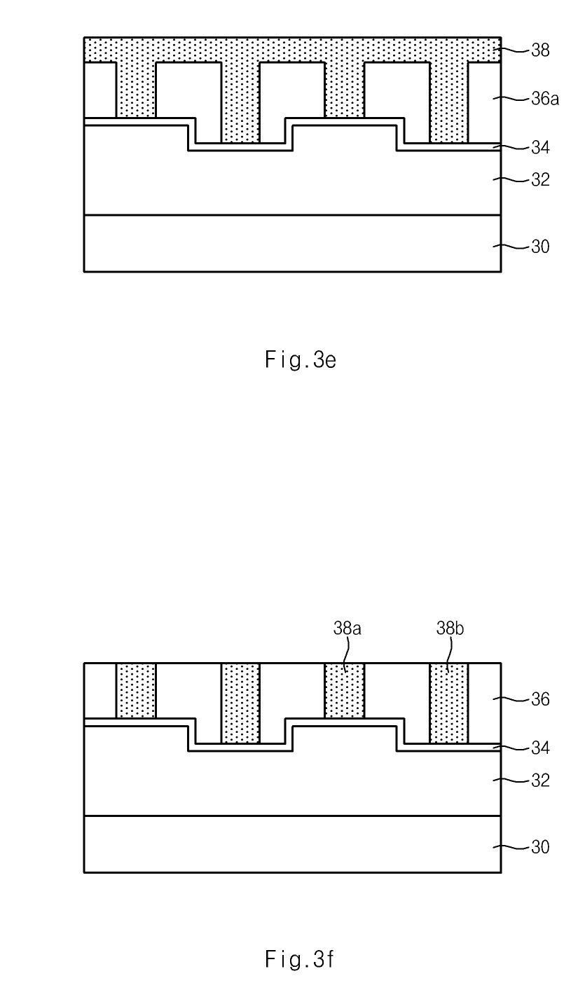

FIGS. 3a to 3f are cross-sectional views illustrating a method for forming a fuse area according to an embodiment of the present invention.

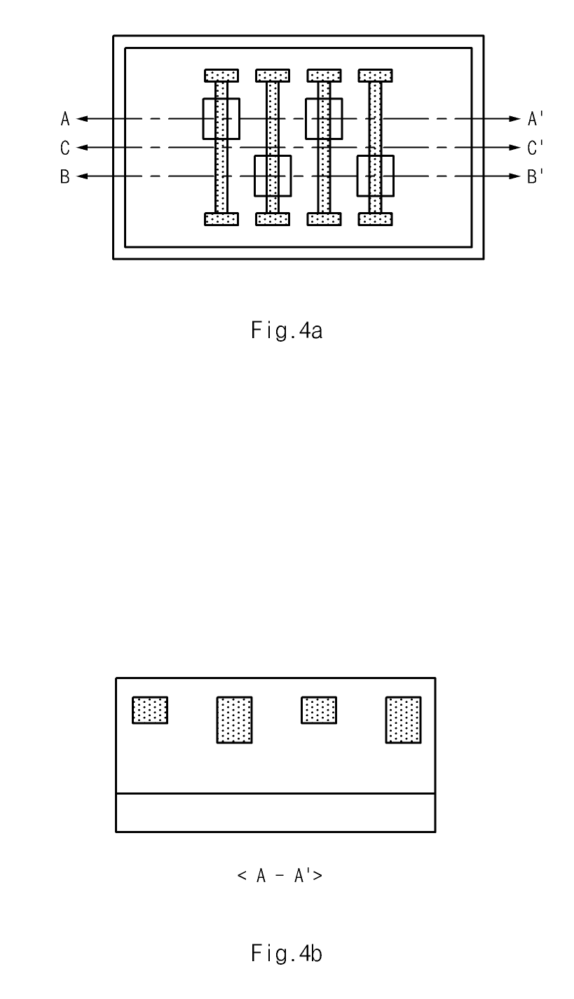

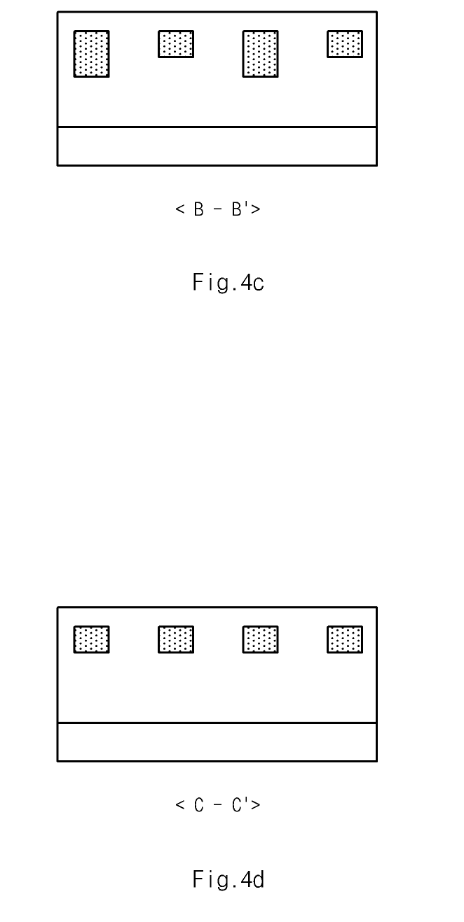

Referring to FIG. 3A, a first interlayer insulating layer 32 is deposited on the semiconductor substrate 30, a photoresist layer (not shown) is deposited on the first interlayer insulating layer 32, and an exposure and development process is performed on the photoresist layer. Subsequently, the first interlayer insulating layer 32 is etched to form a trench. A mask pattern may be used to etch the first interlayer insulating layer 32 to form the trench in fuse area. For example, the mask pattern may include opening parts arranged in a zigzag manner as shown in FIG. 4A, and a detailed description thereof will be described later.

Referring to FIG. 3B, an etching prevention layer 34 is deposited on the entire surface including the first interlayer insulating layer 32. In this case, it is preferable that the etching prevention layer 34 be formed of a silicon nitride layer.

Referring to FIG. 3C, a second interlayer insulating layer 36 is formed on the entire surface including the etching prevention layer 34.

Referring to FIG. 3D, a photoresist layer (not shown) is deposited on the second interlayer insulating layer 36, an exposure and development process and an etch process are sequentially performed, for example, using a mask (not shown), so that a second interlayer insulating layer pattern 36a is formed over the step at the both edges of the trench formed in the fuse area.

Referring to FIG. 3E, metal material (i.e., a metal layer) 38 is deposited on the entire surface including the second interlayer insulating layer pattern 36a so as to fill in the openings defined by the second interlayer insulating layer patterns 36a. In this case, it is preferable that the metal layer 38 be formed of copper (Cu).

Referring to FIG. 3F, the upper part of the metal layer 38 is planarized using, for example, chemical mechanical planarization (CMP) so that the second interlayer insulating layer pattern 36a is exposed, thus generating a first metal pattern 38a formed on an upper step and a second metal pattern 38b formed in the trench (i.e. on a lower step), where the second metal pattern is thicker than the first metal pattern 38a.

The first metal pattern 38a having a smaller thickness is used as a blowing region of each fuse line in a repairing process. The second metal pattern 38b formed thicker in the trench defined by the zigzag-opened mask pattern constitutes the fuse line. Since the fuse line (the second metal pattern 38b) is arranged in a zigzag manner so as to be surrounded by blowing regions (or blowing lines) (the first metal pattern 38a), and the fuse line (the second metal pattern 38b) extends deeper (i.e. thicker) than the blowing line (the first metal pattern 38a), it would not be damaged even when the neighboring blowing regions is cut by laser.

FIG. 4B is a cross-sectional view illustrating a fuse area taken along a line A-A′ of FIG. 4A, FIG. 4C is a cross-sectional view illustrating a fuse area taken along a line B-B′ of FIG. 4A, and FIG. 4D is a cross-sectional view illustrating a fuse area taken along a line C-C′ of FIG. 4A. As shown in FIGS. 4B and 4C, respective metal parts (fuse line and blowing regions) contained in the fuse area are formed to have different thicknesses. Accordingly, if it is assumed that a blowing region is blown at a thin metal part, a fuse line neighboring the blown fuse has a larger thickness so that the neighboring fuse line would remain sufficiently intact to continue functioning properly.

As apparent from the above description, a method for forming a fuse in a semiconductor device according to an embodiment of the present invention forms an interlayer insulating layer, and forms metal lines having different thicknesses from the neighboring metal lines using a zigzag-opened mask, so that it prevents the fuse line next to the blown region from being damaged.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device having a fuse, the method comprising:
depositing a first interlayer insulating layer over a semiconductor substrate;
patterning the first interlayer insulating layer to form a first trench in a fuse area so that the first trench is arranged in a zigzag manner in the fuse area;
depositing a second interlayer insulating layer over the patterned first interlayer insulating layer and within the first trench;
patterning the second interlayer insulating layer to form first and second holes, the second hole extending into the trench and having a greater depth than the first hole; and
filling conductive material in the first and the second holes to form a first metal pattern and a second metal pattern, respectively,
wherein the first metal pattern defines a blowing region and the second metal pattern defines a fuse line.

2. The method according to claim 1, further comprising:
after patterning the first interlayer insulating layer, depositing an etch stop layer over the patterned first interlayer insulating layer.

3. The method according to claim 1, wherein the patterning of the first interlayer insulating layer includes:
depositing a photoresist layer over the first interlayer insulating layer, and
performing an etching process using a mask.

4. The method according to claim 1, wherein the patterning of the second interlayer insulating layer includes:
depositing a photoresist layer on the second interlayer insulating layer, and
performing an exposure and development process using a mask to form a second interlayer insulating layer pattern.

5. The method according to claim 1, wherein the conductive material is formed of copper (Cu).

6. The method according to claim 1, wherein the first and the second metal patterns are arranged alternatively either in horizontal or vertical direction.

7. A semiconductor device having a first fuse, the first fuse comprising:
a first line pattern provided between first and second ends;
a first metal pattern defining a first fuse line and having a first thickness, the first metal pattern being provided between the first end and the second end; and
a second metal pattern defining a first blowing region and having a second thickness, the second metal pattern being provided between the first metal pattern and the second end, the second thickness being different than the first thickness,
wherein the first line pattern comprises the first and second metal patterns.

8. The device of claim 7, further comprising a second fuse provided laterally adjacent to the first fuse, wherein the second fuse comprises:
a second line pattern provided between the first and second ends, the second line pattern including third and fourth metal patterns,
wherein the third metal pattern defines a second fuse line and has the first thickness, the third metal pattern being provided between the first end and second end, and
wherein the fourth metal pattern defines a second blowing region and has the second thickness, the fourth metal pattern being provided between the third metal pattern and the first end.

9. The device of claim 8, wherein the first fuse line and the second blowing region are horizontally aligned to each other, and the second fuse line and the first blowing region are horizontally aligned to each other.

10. The device according to claim 9, wherein the device has a plurality of fuses, each fuse having a blowing region, and
wherein the blowing region of the fuses are arranged in a zigzag manner.
